(19) United States
(12) Patent Application Publication
(10) Pub. No.: US 2024/0291448 A1
(43) Pub. Date: Aug. 29, 2024

(54) POWER AMPLIFIER

(71) Applicant: Samsung Electro-Mechanics Co., Ltd., Suwon-si (KR)

(72) Inventors: Geunyong LEE, Suwon-si (KR); Seungchul PYO, Suwon-si (KR)

(73) Assignee: Samsung Electro-Mechanics Co., Ltd., Suwon-si (KR)

(21) Appl. No.: 18/497,021

(22) Filed: Oct. 30, 2023

(30) Foreign Application Priority Data
Feb. 24, 2023 (KR) 10-2023-0025250

(51) Int. Cl. H03F 3/24; H03F 1/32; H04B 1/04

(52) U.S. Cl. CPC H03F 3/245; H03F 1/32; H04B 1/0458; H03F 2200/451

(57) ABSTRACT

A power amplifier is provided. The power amplifier includes a power transistor configured to amplify input radio frequency (RF) signals; a first transistor that includes a first terminal that provides a bias current to the power transistor; and a linearization circuit that is connected between a terminal to which the input RF signals are input and a first terminal of the first transistor, and is configured to couple a portion of the input RF signals, and provide the coupled input RF signal to the first terminal of the first transistor, in which a magnitude of the coupled signal may be changed according to a power mode.

### CROSS-REFERENCE TO RELATED APPLICATIONS

This application claims the benefit under 35 USC § 119(a) of Korean Patent Application No. 10-2023-0025250 filed on Feb. 24, 2023, in the Korean Intellectual Property Office, the entire disclosure of which is incorporated herein by reference for all purposes.

### BACKGROUND

### 1. Field

The following description relates to a power amplifier.

### 2. Description of the Background

A wireless communication system may apply various digital modulation and demodulation schemes based on the evolution of various communication standards. The existing code division multiple access (CDMA) communication system employs a quadrature phase shift keying (QPSK) method, and a wireless LAN according to the IEEE communication standard employs an orthogonal frequency division multiplexing (OFDM) method. Additionally, long-term evolution (LTE) and LTE-Advanced, which are the 3GPP standards, employ QPSK, quadrature amplitude modulation (QAM), and OFDM schemes. These wireless communication standards may implement a linear modulation method that requires that a magnitude or phase of a transmission signal be maintained during transmission.

In an example, in 5G and sub-6 which are the recent communication standards, as a channel bandwidth becomes wider, the linearity of the communication system is becoming more important. Additionally, high output power for a power amplifier included in a communication system is desired. This makes the linearity of the output power of the power amplifier more important.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a power amplifier includes a power transistor configured to amplify an input radio frequency (RF) signal; a first transistor including a first terminal that provides a bias current to the power transistor; and a linearization circuit that is connected between a terminal to which the input RF signal is input and the first terminal of the first transistor, and is configured to couple a portion of the input RF signal, and provide the coupled input RF signal to the first terminal of the first transistor, wherein a magnitude of the coupled input RF signal is changed based on a power mode.

The power mode may include a low-power mode and a high-power mode, and the magnitude of the coupled input RF signal in the low-power mode may be greater than the magnitude of the coupled input RF signal in the high-power mode.

The power mode may include a low-power mode, a middle-power mode, and a high-power mode, the magnitude of the coupled input RF signal in the low-power mode may be greater than the magnitude of the coupled input RF signal in the middle-power mode, and the magnitude of the coupled input RF signal in the middle power mode may be greater than the magnitude of the coupled input RF signal in the high-power mode.

The linearization circuit may include a variable resistor and a capacitor coupled to each other in series between the terminal to which the input RF signal is input and the first terminal.

A value of the variable resistor may be changed based on the power mode.

The power mode may include a low-power mode and a high-power mode, and the value of the variable resistor in the low-power mode may be less than the value of the variable resistor in the high-power mode.

The power mode may include a low-power mode, a middle-power mode, and a high-power mode, the value of the variable resistor in the low-power mode may be less than the value of the variable resistor in the middle-power mode, and the value of the variable resistor in the middle-power mode may be less than the value of the variable resistor in the high-power mode.

The linearization circuit may include a resistor and a variable capacitor coupled to each other in series between the terminal to which the input RF signal is input and the first terminal.

A value of the variable capacitor may be changed based on the power mode.

The power amplifier may include a resistor connected between the first terminal of the first transistor and an input terminal of the power transistor.

The power amplifier may include a capacitor connected between a base of the first transistor and a ground, wherein the first terminal of the first transistor is an emitter of the first transistor.

In a general aspect, a power amplifier includes a power transistor configured to amplify an input radio frequency (RF) signal; a bias circuit configured to generate a first current to bias the power transistor, and comprising a first terminal that outputs the first current; and a linearization circuit that is connected between a terminal to which the input RF signal is input and the first terminal, and is configured to couple a portion of the input RF signal, and provide the coupled input RF signal to the first terminal, wherein, in a first power mode, the coupled input RF signal has a first magnitude, and in a second power mode, the coupled input RF signal has a second magnitude.

The first power mode may be a mode which outputs power at a lower value than a value in which power of the second power mode is output, and the first magnitude may be greater than the second magnitude.

The first power mode may be a low power mode, and the second power mode may be a high-power mode.

In a third power mode, the coupled input RF signal may have a third magnitude, the first power mode may be a low-power mode, the second power mode may be a middle-power mode, and the third power mode may be a high-power mode, and the first magnitude may be greater than the second magnitude, and the second magnitude may be greater than the third magnitude.

The linearization circuit may include a variable resistor and a capacitor coupled to each other in series between the terminal to which the input RF signal is input and the first terminal.

A value of the variable resistor in the first power mode may be less than a value of the variable resistor in the second power mode.

In a general aspect, a power amplifier includes a bias circuit; and a linearization circuit, connected between a terminal to which a radio frequency (RF) signal is input and an emitter of a transistor of the bias circuit; wherein the linearization circuit includes a capacitor, and a resistor connected in series with the capacitor, wherein a value of one of the resistor and the capacitor is adjusted based on a power mode of the power amplifier.

The resistor may have a first value when the power mode is a first power mode, and has a second value, greater than the first value, when the power mode is a second power mode, the first power mode is a lower power mode than the second power mode.

The capacitor may have a first value when the power mode is a first power mode, and has a second value, less than the first value, when the power mode is a second mode, the first power mode is a lower power mode than the second power mode.

Other features and examples will be apparent from the following detailed description, the drawings, and the claims.

### BRIEF DESCRIPTION OF DRAWINGS

FIG. 1 illustrates an example power amplifier, in accordance with one or more embodiments.

FIG. 2 illustrates an example bias circuit, in accordance with one or more embodiments.

FIG. 3 illustrates an example linearization circuit, in accordance with one or more embodiments.

FIG. 4 illustrates an example variable resistor, in accordance with one or more embodiments.

FIG. 5 illustrates an example linearization circuit, in accordance with one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto. The use of the terms “example” or “embodiment” herein have a same meaning, e.g., the phrasing “in one example” has a same meaning as “in one embodiment”, and “one or more examples” has a same meaning as “in one or more embodiments.”

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Throughout the specification, when a component or element is described as being “on”, “connected to,” “coupled to,” or “joined to” another component, element, or layer it may be directly (e.g., in contact with the other component, element, or layer) “on”, “connected to,” “coupled to,” or “joined to” the other component, element, or layer or there may reasonably be one or more other components, elements, layers intervening therebetween. When a component, element, or layer is described as being “directly on”, “directly connected to,” “directly coupled to,” or “directly joined” to another component, element, or layer there can be no other components, elements, or layers intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Throughout the specification, an RF signal includes Wi-Fi (IEEE 802.11 family, etc.), WiMAX (IEEE 802.16 family, etc.), IEEE 802.20, long term evolution (LTE), Evolution-Data Optimized (Ev-DO), high-speed packet access plus (HSPA+), high-speed downlink packet access plus (HSDPA+), high-speed uplink packet access plus (HSUPA+), Enhanced Data GSM Evolution (EDGE), Global System for Mobile Communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other wireless and wired protocols designated thereafter, but is not limited thereto.

One or more examples may provide a power amplifier with improved linearity.

One or more examples may improve linearity by changing a magnitude of an input RF signal coupled by a linearization circuit according to a power mode.

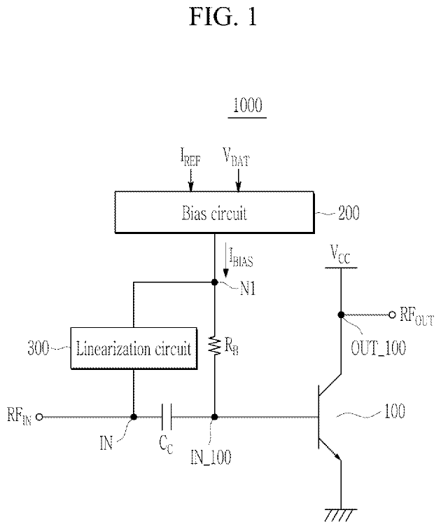

FIG. 1 illustrates an example power amplifier 1000, in accordance with one or more embodiments.

As illustrated in FIG. 1, a power amplifier 1000, in accordance with one or more embodiments, may include a power transistor 100, a bias circuit 200, and a linearization circuit 300.

In FIG. 1, an input RF signal input to the power amplifier 1000 is indicated as ‘RF_{IN}’, and an output RF signal output from the power amplifier 1000 is indicated as ‘RF_{OUT}’. Additionally, a terminal to which the input RF signal RF_{IN} is input is indicated as ‘IN’.

The power transistor 100 may include an input terminal IN_100 and an output terminal OUT_100. The input terminal IN_100 may be a base of the power transistor 100, and the output terminal OUT_100 may be a collector of the power transistor 100. The power transistor 100 may amplify power for an RF signal input to the input terminal IN_100 (i.e., base) and then output the amplified power to an output terminal OUT_100 (i.e., the collector).

In an example, the RF signal to be amplified may be input at the base of the power transistor 100, and the amplified RF signal may be output at a collector of the power transistor 100. An emitter of the power transistor 100 may be connected to a ground, and although not illustrated in FIG. 1, a resistor may be additionally connected between the emitter of the power transistor 100 and the ground. Additionally, the collector of the power transistor 100 may be connected to a power supply voltage V_{CC}, and the power transistor 100 may be operated by the power supply voltage V_{CC}. In an example, the collector of the power transistor 100 may be connected to the power supply voltage V_{CC} through an inductor (not illustrated in FIG. 1) that operates as an RF choke.

The power transistor 100 may be implemented with various transistors such as, but not limited to, a heterojunction bipolar transistor (HBT), a bipolar junction transistor (BJT), and an insulated gate bipolar transistor (IGBT), as only examples. Additionally, although the power transistor 100 is shown as an n-type transistor in FIG. 1, this is only an example, and the power transistor 100 may be a p-type transistor.

The power amplifier 1000, in accordance with one or more embodiments, may further include a coupling capacitor C_{C}. The coupling capacitor C_{C} may be connected between the terminal IN, to which the input RF signal RF_{IN} is input, and the input terminal IN_100 (i.e., base) of the power transistor 100. The coupling capacitor C_{C} may perform an operation of blocking a direct current (DC) component from the RF signal. In non-limiting examples, unlike FIG. 1, the coupling capacitor C_{C} may be disposed in front of the terminal IN or behind the input terminal IN_100. When the arrangement is changed as described above, the terminal IN and the input terminal IN_100 may be the same terminal.

The bias circuit 200 may receive a reference current I_{REF} and a power supply voltage V_{BAT} from external sources. In an example, the power supply voltage V_{BAT} may be a voltage that is supplied from a battery. The bias circuit 200 may generate the bias current I_{BIAS} desired by the power transistor 100 using the reference current I_{REF} and the power supply voltage V_{BAT}. The bias current I_{BIAS} may be supplied to the input terminal IN_100 of the power transistor 100 through a resistor R_{B}, and a bias level (bias point) of the power transistor 100 may be set by the bias current I_{BIAS}.

The power amplifier 1000, in accordance with one or more embodiments, may further include the resistor R_{B}. The resistor R_{B} may be connected between the bias circuit 200 and the input terminal IN_100 of the power transistor 100. In an example, the resistor R_{B} may be a ballast resistor that improves heat dissipation characteristics of the power amplifier 1000. In FIG. 1, a node where the bias circuit 200 and the resistor R_{B} are connected to each other is indicated as ‘N1’. In an example, in FIG. 1, the resistor R_{B} is illustrated as a separate component that is not included in the bias circuit 200. However, this is only an example, and, in an example, the resistor R_{B} may be included in the bias circuit 200.

The linearization circuit 300 may be connected between the terminal IN and the node N1. The linearization circuit 300 may improve the linearity of the output power of the power transistor 100. As the output power (i.e., gain) of the power transistor 100 increases, a base voltage droop of the power transistor 100 may occur, and the linearization circuit 300 may compensate for the base voltage droop of the power transistor 100 using the input RF signal RF_{IN}. A base voltage droop refers to a slope with respect to power, and is the loss in output voltage from a device as it drives a high power.

When the output power (gain) of the power transistor 100 increases, the bias current I_{BIAS} may also increase. As the bias current I_{BIAS} increases, a voltage difference between both terminals of the resistor R_{B} increases, and as a result, the base voltage of the power transistor 100 may decrease. The linearization circuit 300 may compensate for this base voltage droop of the power transistor 100. The linearization circuit 300, in accordance with one or more embodiments, may adjust the amount of coupling to the input RF signal RF_{IN} according to the power mode of the power amplifier 1000. By operation of the linearization circuit 300, some, or a portion, of the input RF signals RF_{IN} may be coupled and output to a node N1. Hereinafter, the coupled input RF signal RF_{IN} is referred to as a ‘coupled input RF signal’. A specific configuration and operation of the linearization circuit 300 will be described in more detail below.

Although not illustrated in FIG. 1, the power amplifier 1000 according to an embodiment may further include an input matching network and an output matching network. The input matching network may be connected to the terminal IN, and may perform impedance matching between the input RF signal RF_{IN} and the power transistor 100. The output matching network may be connected to the output terminal OUT_100 (i.e., collector) of the power transistor 100, and may perform impedance matching between an output RF signal RF_{OUT} and a next stage (i.e., the next stage of the power amplifier 1000). Each of the input matching network and the output matching network may be implemented as a combination of at least one of a resistor, an inductor, and a capacitor, as only examples.

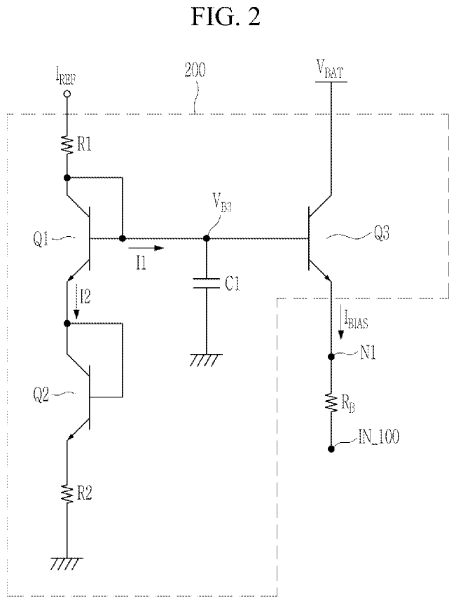

FIG. 2 illustrates the bias circuit 200, in accordance with one or more embodiments.

As illustrated in FIG. 2, the bias circuit 200, in accordance with one or more embodiments may include a transistor Q1, a transistor Q2, a transistor Q3, a resistor R1, a resistor R2, and a capacitor C1.

The transistors Q1 to Q3 may be implemented with various transistors such as, but not limited to, a heterojunction bipolar transistor (HBT), a bipolar junction transistor (BJT), and an insulated gate bipolar transistor (IGBT), as only examples. Additionally, the transistors Q1 to Q3 are illustrated as n-type transistors in FIG. 2. However, this is only an example, and the transistors Q1 to Q3 may be replaced with p-type transistors. In an example, since each of the bases of the transistors Q1 to Q3 may operate as a control terminal, the term ‘control terminal’ may be used. Since each of the collectors of the transistors Q1 to Q3 are one terminal of the transistor, the term ‘first terminal or second terminal’ may be used. Since each of the emitters of the transistors Q1 to Q3 are one terminal of the transistor, the term ‘first terminal or second terminal’ may be used.

Additionally, in an example, the base and the collector of the transistors Q1 may be connected to each other, and the collector of the transistor Q1 may receive a reference current I_{REF} through the resistor R1. In an example, the transistor Q1 may have a diode connection structure. The transistor Q1 may operate to sink a current I2 from reference current I_{REF}. In an example, the reference current I_{REF} may be a current source.

The base and collector of the transistor Q2 may be connected to each other, and the collector of the transistor Q2 may be connected to the emitter of transistor Q1. The transistor Q2 may have a diode connection structure, and the emitter of the transistor Q2 may be connected to a ground.

In an example, the resistor R2 may be connected between the emitter of the transistor Q2 and the ground.

The collector of the transistor Q3 may be connected to the power supply voltage V_{BAT}, and the base of transistor Q3 may be connected to the base of transistor Q1. In FIG. 2, the base voltage of the transistor Q3 is indicated as ‘V_{B3}’. Additionally, the emitter of the transistor Q3 may be connected to the input terminal IN_100 of the power transistor 100 through the resistor R_{B}. That is, the emitter of the transistor Q3 may supply the bias current I_{BIAS} to the power transistor 100 through the resistor R_{B}. As illustrated in FIG. 2, the node N1 described in FIG. 1 may be a node where the transistor Q3 and the resistor R_{B} are connected to each other.

The capacitor C1 may be connected between the base of transistor Q3 and the ground. The capacitor C1 may stabilize a base voltage V_{B3} of the transistor Q3 and reduce the impedance of the transistor Q3.

The reference current I_{REF} may be divided into a current I1 and a current I2, and the current I1 may be input to the base of the transistor Q3. Accordingly, the bias current I_{BIAS} may be determined corresponding to the current I1. Additionally, the bias current I_{BIAS} may be determined corresponding to the base voltage V_{B3} of the transistor Q3. In an example, when the base voltage V_{B3} of the transistor Q3 increases, the bias current I_{BIAS} may increase.

As described in FIG. 1, the linearization circuit 300 may output the coupled input RF signal to the node N1. The coupled input RF signal may be input to the emitter of transistor Q3, and thus, may increase the bias current I_{BIAS}. The base voltage droop of the power transistor 100 may be compensated for by increasing the bias current I_{BIAS}. That is, the linearization circuit 300 may compensate for the base voltage droop of the power transistor 100.

The degree of compensation for the base voltage droop of the power transistor 100 may vary according to the magnitude of the coupled input RF signal. As the coupled input RF signal increases, the base voltage droop of power transistor 100 may be more compensated for.

In an example, in FIG. 1, in order to improve the efficiency of the power amplifier 1000, the value of the power supply voltage V_{CC} may be changed according to the power mode. In an example, the power mode may include a high-power mode (HPM) and a low-power mode (LPM). The value of the power supply voltage V_{CC} may be set to a lower value in the low-power mode (LPM) than in the high-power mode (HPM). In another example, the power mode may include a high-power mode (HPM), a middle-power mode (MPM), and a low-power mode (LPM). The value of the power supply voltage V_{CC} may be set to a lower value in the low-power mode (LPM) than in the middle-power mode (MPM). Additionally, the value of the power supply voltage V_{CC} may be set to a lower value in the middle power mode (MPM) than in the high-power mode (HPM). As the value of the power supply voltage V_{CC} decreases, the linearity of the power amplifier 1000 may further deteriorate. In an example, the linearity of the power amplifier 1000 may further deteriorate in the low power mode (LPM) than in the high-power mode (HPM).

Accordingly, the linearization circuit 300, in accordance with one or more embodiments, may adjust the magnitude (amount) of coupling to the input RF signal RF_{IN} according to the power mode. That is, the coupled input RF signal output from the linearization circuit 300 may have a different magnitude (amount) according to the power mode. In an example, the magnitude of the coupled input RF signal may be the power of the coupled input RF signal.

In an example, the coupling magnitude (magnitude of the coupled input RF signal) of the linearization circuit 300 may be larger in the low-power mode (LPM) than in the high-power mode (HPM). That is, the magnitude of the coupled input RF signal may have the relationship of Equation 1 below according to the power mode.

$${COUPLED\_RF}_{IN} \_LPM > {COUPLED\_RF}_{IN} \_HPM \qquad Equation 1$$

In Equation 1, COUPLED_RF_{IN}_LPM represents the magnitude of the coupled input RF signal in the low-power mode, and COUPLED_RF_{IN}_HPM represents the magnitude of the coupled input RF signal in the high-power mode.

In another example, the coupling magnitude (magnitude of the coupled input RF signal) of the linearization circuit 300 may be larger in the low-power mode (LPM) than in the middle-power mode (MPM). In an example, the coupling magnitude (magnitude of the coupled input RF signal) of the linearization circuit 300 may be larger in the middle-power mode (MPM) than in the high-power mode (HPM). That is, the magnitude of the coupled input RF signal may have the relationship of Equation 2 below according to the power mode.

$${COUPLED\_RF}_{IN} \_LPM > {COUPLED\_RF}_{IN} \_MPM > {COUPLED\_RF}_{IN} \_HPM \qquad Equation 2$$

In Equation 2, COUPLED_RF_{IN}_MPM represents the magnitude of the coupled input RF signal in the middle-power mode.

Through this, the linearization circuit 300, in accordance with one or more embodiments, may compensate for the deterioration of linearity as the power mode decreases.

Hereinafter, a method of adjusting the magnitude of the coupling to the input RF signal RF_{IN} according to the power mode of the linearization circuit 300 will be described.

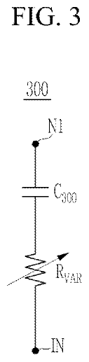

FIG. 3 illustrates the linearization circuit 300, in accordance with one or more embodiments.

As illustrated in FIG. 3, the linearization circuit 300, in accordance with one or more embodiments, may include a variable resistor R_{VAR} and a capacitor C₃₀₀.

A first end of the variable resistor R_{VAR} may be connected to the terminal IN, and a second end of the variable resistor R_{VAR} may be connected to a first end of the capacitor C₃₀₀. The first end of the capacitor C₃₀₀ may be connected to the second end of the variable resistor R_{VAR}, and the second end of the capacitor C₃₀₀ may be connected to the node N1. In an example, unlike FIG. 3, the positions of the variable resistor R_{VAR} and the capacitor C₃₀₀ may be changed. That is, a first end of the capacitor C₃₀₀ may be connected to the terminal IN, and the variable resistor R_{VAR} may be connected between the second end of the capacitor C₃₀₀ and the node N1.

In other words, the variable resistor R_{VAR} and the capacitor C₃₀₀ may be connected in series with each other between the terminal IN and the node N1. Some of the input RF signals RF_{IN} may be transmitted to the node N1 through the variable resistor R_{VAR} and the capacitor C₃₀₀. That is, the linearization circuit 300 may output the coupled input RF signal to the node N1 through the variable resistor R_{VAR} and the capacitor C₃₀₀.

Depending on the value of the variable resistor R_{VAR}, the magnitude of the coupled input RF signal may be changed. As the value of the variable resistor R_{VAR} decreases, the magnitude of the coupled input RF signal may increase. That is, since the resistance attenuates the RF signal, the magnitude of the coupled input RF signal may be adjusted by adjusting the value of the variable resistor R_{VAR}.

The variable resistor R_{VAR} may be changed according to the power mode. As an example, the value of the variable resistor R_{VAR} may be smaller in the low-power mode (LPM) than in the high-power mode (HPM). That is, the value of the variable resistor R_{VAR} may have the relationship of Equation 3 below according to the power mode.

$${R}_{VAR} \_LPM < {R}_{VAR} \_HPM \qquad Equation 3$$

In Equation 3, R_{VAR}_LPM represents the value of the variable resistor R_{VAR} in the low-power mode (LPM), and R_{VAR}_HPM represents the value of the variable resistor R_{VAR} in the high-power mode (HPM).

In another example, the variable resistor R_{VAR} may be smaller in the low-power mode (LPM) than in the middle-power mode (MPM). Additionally, the variable resistor R_{VAR} may be smaller in the middle-power mode MPM than in the high-power mode HPM. That is, the value of the variable resistor R_{VAR} may have the relationship of Equation 4 below according to the power mode.

$${R}_{VAR} \_LPM < {R}_{VAR} \_MPM < {R}_{VAR} \_HPM \qquad Equation 4$$

In Equation 4, R_{VAR}_MPM represents the value of the variable resistor R_{VAR} in the middle-power mode MPM.

In an example, various methods may be used to change the value of the variable resistor R_{VAR} according to the power mode.

Hereinafter, in an example, a method of changing a value of a variable resistor R_{VAR} through a switch will be described.

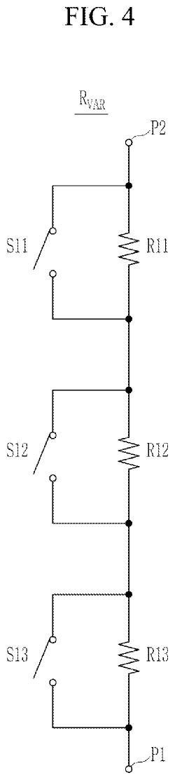

FIG. 4 is a diagram illustrating an example of the variable resistor R_{VAR}.

As illustrated in FIG. 4, the variable resistor R_{VAR} may include a resistor R11, a resistor R12, a resistor R13, a switch S11, a switch S12, and a switch S13. A terminal P1 may be disposed at a first end of the variable resistor R_{VAR}, and a terminal P2 may be disposed at a second end of the variable resistor R_{VAR}.

The resistor R11, the resistor R12, and the resistor R13 may be connected in series with each other between the two terminals P1 and P2. That is, a first end of the resistor R11 may be connected to the terminal P2, and a first end of the resistor R12 may be connected to the second end of the resistor R11. Additionally, the resistor R13 may be connected between the second end of the resistor R12 and the terminal P1.

The switch S11 may be connected in parallel to both ends of the resistor R11, and the switch S12 may be connected in parallel to both ends of the resistor R12. Additionally, the switch S13 may be connected to both ends of the resistor R13. The switch S11, the switch S12, and the switch S13 may be switched based on the determined power mode.

In the low-power mode (LPM), two of the switches S11 to S13 may be turned on and the other switch of the switches S11 to S13 may be turned off. In an example, the switches S12 and S13 may be turned on and the switch S11 may be turned off, and as a result, the value of the resistor R11 may be the value of the variable resistor R_{VAR}.

In the middle-power mode (MPM), one of the switches S11 to S13 may be turned on and the other two switches of the switches S11 to S13 may be turned off. In an example, the switch S13 may be turned on and the switches S11 and S12 may be turned off, and as a result, the sum of the value of the resistor R11 and the value of the resistor R12 may be the value of the variable resistor R_{VAR}.

In the high-power mode (HPM), all of the switches S11 to S13 may be turned off. Accordingly, the sum of the value of the resistor R11, the value of the resistor R12, and the value of the resistor R13 may be the value of the variable resistor R_{VAR}.

Although the method of changing the value of the variable resistor (R_{VAR}) according to the power mode through three resistors and three switches has been described with reference to FIG. 4, this is only an example, and the method of changing the value of the variable resistor (R_{VAR}) may also be implemented through two resistors and two switches.

Additionally, the value of the variable resistor R_{VAR} may be changed according to the power mode through four or more resistors and four or more switches. Although an example of three power modes has been described with reference to FIG. 4, this is only an example, and the above method may be applied to two power modes (e.g., LPM and HPM). A detailed description of these examples may be known to those skilled in the art to which this disclosure belongs, and therefore, detailed descriptions thereof will be omitted.

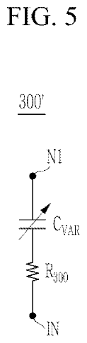

FIG. 5 illustrates a linearization circuit 300′, in accordance with one or more embodiments.

As illustrated in FIG. 5, the linearization circuit 300′, in accordance with one or more embodiments, may include a resistor R₃₀₀ and a variable capacitor C_{VAR}.

A first end of the resistor R₃₀₀ may be connected to the terminal IN and the second end of the resistor R₃₀₀ may be connected to a first end of the variable capacitor C_{VAR}. The first end of the variable capacitor C_{VAR} may be connected to the second end of the resistor R₃₀₀, and the second end of the variable capacitor C_{VAR} may be connected to the node N1. In an example, unlike FIG. 5, positions of the resistor R₃₀₀ and the variable capacitor C_{VAR} may be changed. That is, a first end of the variable capacitor C_{VAR} may be connected to the terminal IN, and the resistor R₃₀₀ may be connected between the second end of the variable capacitor C_{VAR} and the node N1.

In other words, the resistor R₃₀₀ and the variable capacitor C_{VAR} may be connected in series with each other between the terminal IN and the node N1. Some of the input RF signals RF_{IN} may be transmitted to the node N1 through the resistor R₃₀₀ and the variable capacitor C_{VAR}. That is, the linearization circuit 300′ may output the coupled input RF signal to the node N1 through the resistor R₃₀₀ and the variable capacitor C_{VAR}.

Depending on the value of the variable capacitor C_{VAR}, the magnitude of the coupled input RF signal may be changed. As the value of the variable capacitor C_{VAR} increases, the magnitude of the coupled input RF signal may increase. That is, the magnitude of the coupled input RF signal may be adjusted by adjusting the value of the variable capacitor C_{VAR}.

The variable capacitor C_{VAR} may be changed according to the determined power mode. In an example, the value of the variable capacitor C_{VAR} may be larger in the low-power mode (LPM) than in the high-power mode (HPM). That is, the value of the variable capacitor C_{VAR} may have the relationship of Equation 5 below according to the determined power mode.

$${C}_{VAR} \_LPM > {C}_{VAR} \_HPM \qquad Equation 5$$

In Equation 3, C_{VAR}_LPM represents the value of the variable capacitor C_{VAR} in the low-power mode (LPM), and C_{VAR}_HPM represents the value of the variable capacitor C_{VAR} in the high-power mode (HPM).

In another example, the variable capacitor C_{VAR} may be larger in the low-power mode (LPM) than in the middle-power mode (MPM). Additionally, the variable capacitor C_{VAR} may be larger in the middle-power mode (MPM) than in the high-power mode (HPM). That is, the value of the variable capacitor C_{VAR} may have the relationship of Equation 6 below according to the determined power mode.

$${C}_{VAR} \_LPM > {C}_{VAR} \_MPM > {C}_{VAR} \_HPM \qquad Equation 6$$

In Equation 6, C_{VAR}_MPM represents the value of the variable capacitor R_{VAR} in the middle-power mode MPM.

In an example, the variable capacitor C_{VAR} may be implemented through a varactor diode. Additionally, the variable capacitor C_{VAR} may be implemented through a plurality of capacitors and a plurality of switches similarly to the method of FIG. 4.

While this disclosure includes specific examples, it will be apparent to one of ordinary skill in the art, after an understanding of the disclosure of this application, that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A power amplifier, comprising:
a power transistor configured to amplify an input radio frequency (RF) signal;
a first transistor comprising a first terminal that provides a bias current to the power transistor; and
a linearization circuit that is connected between a terminal to which the input RF signal is input and the first terminal of the first transistor, and is configured to couple a portion of the input RF signal, and provide the coupled input RF signal to the first terminal of the first transistor,
wherein a magnitude of the coupled input RF signal is changed based on a power mode.

2. The power amplifier of claim 1, wherein:
the power mode comprises a low-power mode and a high-power mode, and
the magnitude of the coupled input RF signal in the low-power mode is greater than the magnitude of the coupled input RF signal in the high-power mode.

3. The power amplifier of claim 1, wherein:
the power mode comprises a low-power mode, a middle-power mode, and a high-power mode,
the magnitude of the coupled input RF signal in the low-power mode is greater than the magnitude of the coupled input RF signal in the middle-power mode, and
the magnitude of the coupled input RF signal in the middle power mode is greater than the magnitude of the coupled input RF signal in the high-power mode.

4. The power amplifier of claim 1, wherein:
the linearization circuit comprises a variable resistor and a capacitor coupled to each other in series between the terminal to which the input RF signal is input and the first terminal.

5. The power amplifier of claim 4, wherein a value of the variable resistor is changed based on the power mode.

6. The power amplifier of claim 5, wherein:
the power mode comprises a low-power mode and a high-power mode, and
the value of the variable resistor in the low-power mode is less than the value of the variable resistor in the high-power mode.

7. The power amplifier of claim 5, wherein:
the power mode comprises a low-power mode, a middle-power mode, and a high-power mode,
the value of the variable resistor in the low-power mode is less than the value of the variable resistor in the middle-power mode, and
the value of the variable resistor in the middle-power mode is less than the value of the variable resistor in the high-power mode.

8. The power amplifier of claim 1, wherein:
the linearization circuit comprises a resistor and a variable capacitor coupled to each other in series between the terminal to which the input RF signal is input and the first terminal.

9. The power amplifier of claim 8, wherein a value of the variable capacitor is changed based on the power mode.

10. The power amplifier of claim 1, further comprising:
a resistor connected between the first terminal of the first transistor and an input terminal of the power transistor.

11. The power amplifier of claim 10, further comprising:
a capacitor connected between a base of the first transistor and a ground,
wherein the first terminal of the first transistor is an emitter of the first transistor.

12. A power amplifier, comprising:
a power transistor configured to amplify an input radio frequency (RF) signal;
a bias circuit configured to generate a first current to bias the power transistor, and comprising a first terminal that outputs the first current; and
a linearization circuit that is connected between a terminal to which the input RF signal is input and the first terminal, and is configured to couple a portion of the input RF signal, and provide the coupled input RF signal to the first terminal,
wherein, in a first power mode, the coupled input RF signal has a first magnitude, and in a second power mode, the coupled input RF signal has a second magnitude.

13. The power amplifier of claim 12, wherein:
the first power mode is a mode which outputs power at a lower value than a value in which power of the second power mode is output, and
the first magnitude is greater than the second magnitude.

14. The power amplifier of claim 13, wherein the first power mode is a low power mode, and the second power mode is a high-power mode.

15. The power amplifier of claim 12, wherein:
in a third power mode, the coupled input RF signal has a third magnitude,
the first power mode is a low-power mode, the second power mode is a middle-power mode, and the third power mode is a high-power mode, and
the first magnitude is greater than the second magnitude, and the second magnitude is greater than the third magnitude.

16. The power amplifier of claim 12, wherein:
the linearization circuit comprises a variable resistor and a capacitor coupled to each other in series between the terminal to which the input RF signal is input and the first terminal.

17. The power amplifier of claim 16, wherein a value of the variable resistor in the first power mode is less than a value of the variable resistor in the second power mode.

18. A power amplifier, comprising:
a bias circuit; and
a linearization circuit, connected between a terminal to which a radio frequency (RF) signal is input and an emitter of a transistor of the bias circuit;
wherein the linearization circuit comprises:
a capacitor, and
a resistor connected in series with the capacitor,
wherein a value of one of the resistor and the capacitor is adjusted based on a power mode of the power amplifier.

19. The power amplifier of claim 18, wherein the resistor has a first value when the power mode is a first power mode, and has a second value, greater than the first value, when the power mode is a second power mode, the first power mode is a lower power mode than the second power mode.

20. The power amplifier of claim 18, wherein the capacitor has a first value when the power mode is a first power mode, and has a second value, less than the first value, when the power mode is a second mode, the first power mode is a lower power mode than the second power mode.
